(19) United States
(12) Patent Application Publication
(10) Pub. No.: US 2025/0359495 A1
(43) Pub. Date: Nov. 20, 2025

(54) Phase Change Switch Device

(71) Applicant: Infineon Technologies AG, Neubiberg (DE)

(72) Inventors: Semen Syroiezhin, Erlangen (DE); Valentyn Solomko, München (DE); Dominik Heiss, München (DE); Christian Butschkow, München (DE); Jochen Braumüller, Holzkirchen (DE)

(21) Appl. No.: 18/869,476

(22) PCT Filed: May 26, 2023
(86) PCT No.: PCT/EP2023/064231

§ 371 Date: Nov. 26, 2024

(30) Foreign Application Priority Data
May 27, 2022 (EP) 22175816.2

(51) Int. Cl. H10N 70/00; H10N 70/20; H10N 79/00

(52) U.S. Cl. CPC H10N 70/8413; H10N 70/231; H10N 79/00

(57) ABSTRACT

A phase change switch device is provided, including: a first phase change switch including a phase change material, a heater device arranged to heat the phase change material, a first switch terminal electrically coupled to the phase change material, a second switch terminal electrically coupled to the phase change material, a first heater supply terminal electrically coupled to the heater and a second heater supply terminal electrically coupled to the heater, a second phase change switch including a phase change material, a heater device arranged to heat the phase change material, a first switch terminal electrically coupled to the phase change material, a second switch terminal electrically coupled to the phase change material, a first heater supply terminal electrically coupled to the heater and a second heater supply terminal electrically coupled to the heater, wherein the first switch terminal of the second phase change switch is electrically coupled to the first heater supply terminal of the second phase change switch.

### TECHNICAL FIELD

The present application relates to phase change switch devices and to methods of operating phase change switch devices.

### BACKGROUND

The technical requirements for radio frequency (RF) applications using high frequencies, such as radar sensing and mobile communication according to the 5G standard, are increasing. In particular, switches having improved characteristics compared to state-of-the-art CMOS switches will be required to meet future demands. Phase change switches are considered as promising candidates for switching RF signals. Such phase change switches use a phase change material (PCM) which typically exhibits a higher electric conductivity in a crystalline phase state than in an amorphous phase state. By changing the phase state of the phase change material, a switch device including such a material may be switched on and off.

For example, to change the phase state from amorphous to crystalline, typically a heater is employed heating the phase change material causing crystallization. This switching on by causing crystallization is also referred to as a set operation. In the set operation, the heater is actuated in such a way that the temperature of the phase change material is above its crystallization temperature, typically about 250° C., but below the melt temperature typically in a range of 600° C. to 900° C., for example. The length of the heating pulse caused by the heater is chosen such that any amorphous region present in the PCM can regrow into the crystalline phase state.

When switching off the switching device, also referred to as reset operation, the heater is actuated in such a way that the temperature of the PCM is raised above the melt temperature (for example above about 600° C. to 900° C.) followed by a comparatively rapid cooldown which freezes the phase change material into an amorphous state. The heater, also referred to as heater device herein, is typically a resistive heater made of a thin-film conductive layer, for example tungsten, and is used to produce local temperature gradients with the defined profile to change the phase-change material between the crystalline and amorphous states.

Suitable phase change materials used for such phase change switches include germanium telluride (GeTe) or germanium-antimony-tellurium (GeSbTe, usually referred to as GST), and heaters may be made of a material like polycrystalline silicon or tungsten.

When used for example in antenna tuning applications, phase change switches are used to switch radio frequency signals, for example in the GHz range. Practical RF voltages required by antenna tuning applications can be as high as 100V. It is difficult to design a PCM device that can withstand this voltage with a grounded heater due to the high capacitive coupling between the heater and the PCM, which results in a non-uniform voltage distribution across the PC material and therefore reduced voltage handling. Additionally, stacking several switches will not scale up the voltage handling as desired due to the leakage path to ground via the first heater in the stack.

### SUMMARY

A phase change switch device as defined in claim 1 or 4 and a method as defined in claim 16 are provided. The dependent claims define further embodiments.

### BRIEF DESCRIPTION OF THE DRAWINGS

FIGS. 1A-1D illustrate the configuration of phase change switches used in embodiments and naming conventions for terminals used herein.

FIGS. 2, 3A-3C, 4A-4C and 5A-5E illustrates a phase change switch devices according to various embodiments.

FIG. 6 is a flowchart illustrating a method according to an embodiment.

### DETAILED DESCRIPTION

In the following, various embodiments will be described in detail referring to the attached drawings. The embodiments described hereinafter are to be taken as examples only and are not to be construed as limiting. For example, while in embodiments specific arrangements or components are provided, in other embodiments other configurations may be used.

Besides features (or for example components, elements, acts, events or the like) explicitly shown and described, in other embodiments additional features may be provided, for example features used in conventional switch devices using phase change materials. For example, embodiments described herein relate to specific couplings and arrangement of a plurality of phase change switches, and other components and features, like spatial arrangement of heaters and phase change material, radio frequency (RF) circuitry using the switch device and the like may be implemented in a conventional manner. Such RF circuitry may be integrated with the described switch devices on the same substrate, but may also be provided separately for example, on one or more separate chip dies, which in some implementations then may be combined with a switch device in a common package. Also, manufacturing implementations like providing phase change material on a substrate like a silicon substrate to implement a phase change switch, providing phase change material in a trench in a silicon substrate for manufacturing the switch device and the like may be performed in any conventional manner.

A switch based on a phase change material (PCM) will be referred to as a phase change switch or short PCS or PCM switch herein. As explained in the introductory portion, such phase change switches may be set to a crystalline phase state or an amorphous phase change, thus changing the resistance of the phase change material and therefore of the switch by several orders of magnitude. In this way, for example an on resistance of a switch in a range of 1 to 100 Q may be achieved, whereas an off-resistance may be several orders of magnitude higher, for example at least in the Kiloohm range.

Implementation details described with respect to one of the embodiments are also applicable to other embodiments.

Phase change switch devices as discussed herein include a plurality of individual phase change switches.

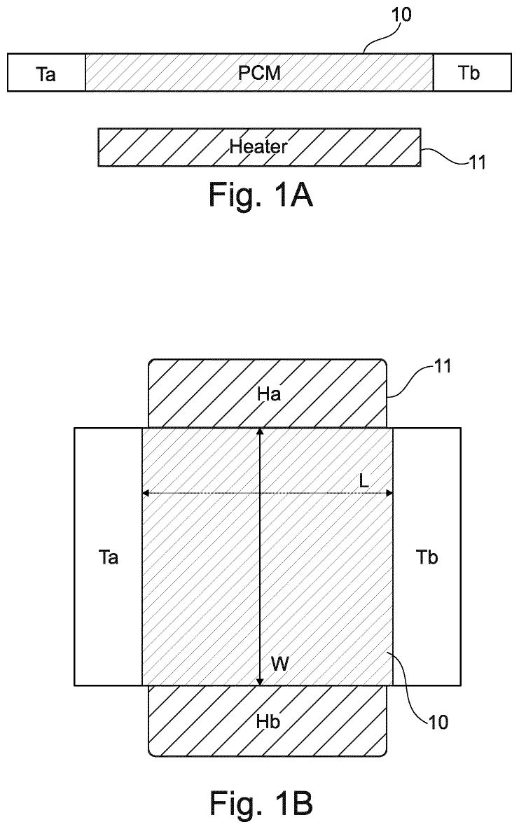

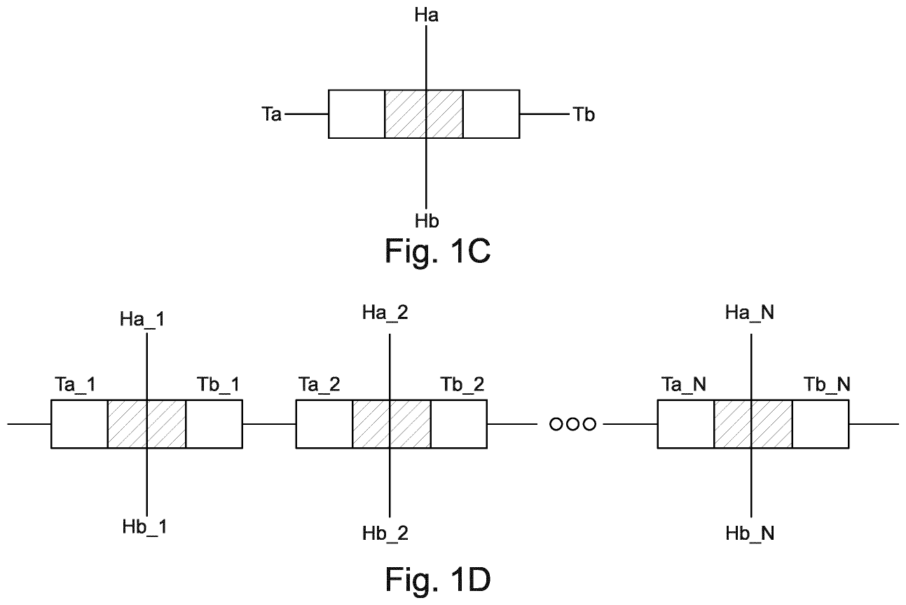

Before discussing embodiments in detail, with respect to FIGS. 1A-1D implementation examples of phase change switches useable in embodiments and terminology used in the following will be explained.

The layout and cross-section of an example for a PCS useable in embodiments is shown in FIG. 1A and 1B, wherein FIG. 1A shows a cross-sectional view and FIG. 1B shows a top view. FIG. 1C shows a simplified representation used herein. That means that the representation of FIG. 1C will be used in the following Figures to represent a PCS. The PCS has two terminals Ta and Tb for electrically contacting a phase change material (PCM) 10, also referred to as switch terminals. Depending on the state of PCM 10 (crystalline or amorphous), the ohmic resistance provided by PCM 10 between switch terminals Ta, Tb is low (on-state) or high (off-state) as explained above, thus providing a switch functionality.

Ha, Hb are terminals of a heater 11. Heater 11 is used to selectively heat PCM 10 to change between the amorphous and crystalline state, as in A typical width W of PCM 10 for antenna tuning applications can be as high as hundreds of micrometers. A length L can vary between about ˜0.5 um and several micrometers. PCM 10 and heater 11 are separated by a dielectric layer (e.g. SiN, AolN; not shown in FIGS. 1A-1D), which typically has a thickness between 50 and 100 nm. On the one hand this layer should be thin to allow efficient thermal coupling between heater and PCM; on the other hand it should be thick to minimize capacitive coupling between the two. Therefore, the thickness of this layer is usually a compromise between thermal coupling and capacitive coupling. In some applications, one of the switch terminals Ta, Tb is grounded for a shunt switch configuration which will be used as a particular example hereinafter. However, embodiments shown may also be used in other configurations and applications. Both heater terminals conventionally are well grounded by an actuation circuit during RF operation which is acceptable for low-voltage switches, but causes issues in high-voltage design. Therefore, in some embodiments discussed herein the heater may be decoupled from ground by a further PCS.

Practical RF voltages required by antenna tuning applications can be as high as 100V. It is difficult to design a PCM device that can withstand this voltage with a grounded heater due to the high capacitive coupling between the heater and the PCM, which results in a non-uniform voltage distribution across the PC material and therefore reduced voltage handling. Additionally, stacking several switches will not scale up the voltage handling as desired due to the leakage path to ground via the first heater in the stack. FIG. 1D shows such a stack, where N PCS are coupled in series to increase the voltage tolerance. In case of N PCS as in FIG. 1D, a number is added to the terminals Ta, Tb, Ha and Hb to each switch, i.e. Ta_1, Tb_1, Ha_1, Hb_1 for the first switch, Ta_2, Tb_2, Ha_2, Hb_2 for the second switch etc.

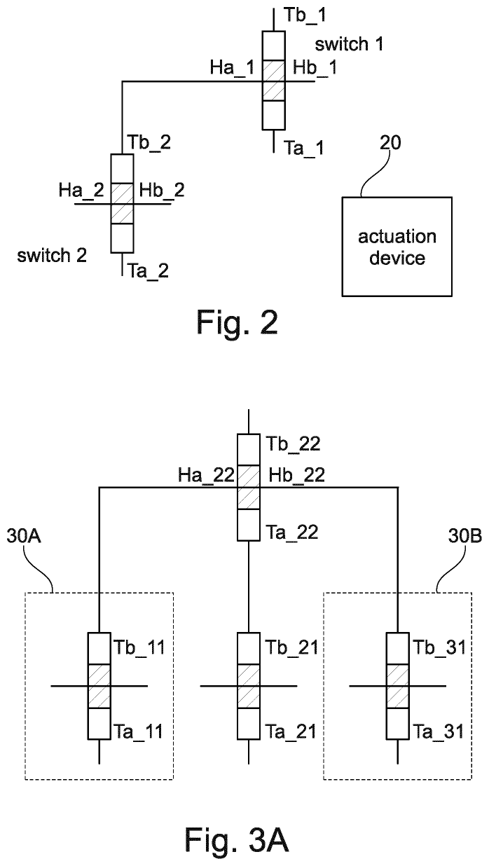

FIG. 2 shows a smallest unit, e.g. building block, part or whole, of phase change switch device, e.g., a high voltage PCM RF switch devices according to an embodiment that comprises 2 PCM switches. Switch 1 having switch terminals Tb_1, Ta_1 and heater terminals Ha_1, Hb_1 participates in establishing of a switchable RF path vial terminals Tb_1,Ta_1 and the PCM of switch 1. In other words, switch 1 serves to switch a signal like an RF signal e.g. for antenna tuning purposes. Switch terminal Tb_2 of switch 2 is connected to heater terminal Ha_1 of switch 1. Switch 2 is used to drive the heater of the first switch. For example, an actuation device 20 for changing the switch state of switch 1 between on and off supplies power for heating the heater of switch 1 via switch 2, for example by providing the power to terminal Ta_2 when switch 2 is switched on, and provides power to the heater of switch 2 (e.g. at terminal Ha_2) to switch switch 2 on. Actuation device 20 may include is a high power biasing structure which provides a voltage or current pulse of desired form and duration through the heater in order to switch the PCM of the respective switch from the crystalline to the amorphous phase and vice versa which defines a switching event for the respective switch, for example for an RF path between switch terminals Tb1, Ta1 in case switch 1 is switched or for the path for supplying power to the heater of switch 1 when switch 2 is switched.

The second switch in some embodiments may be an auxiliary switch, i.e. it does not participate in establishing of the switchable path switching the signal, e.g. RF signal. In other embodiments, it switch 2 may be a contributor to the RF path, i.e. directly participate in the switching of the signal. In the latter case, switch 2 has a double function, both as auxiliary switch for heating and as a signal, e.g. RF, switch. In this case, for example and switch terminal Tb_2 may additionally be coupled to switch terminal Ta_1.

In embodiments, switch 2 establishes a low-ohmic connection to the heater of switch 1 during the actuation or heating phase (by switch 2 being switched on) and high-ohmic connection during operation phase, e.g. RF operation, where an RF signal is applied to switch 1 (by switch 2 being switched off). The high-ohmic connection when switch 2 is switched off may be a primarily capacitive coupling based on a capacitance between switch terminals Ta_2, Tb_2 when the PCM of switch 2 is in the high-ohmic (amorphous) state. The high-ohmic connection in embodiments may maximize the voltage handling capabilities of the phase change switch device by decreasing of the coupling between the PCM of switch 1 and ground through the heaters and improving voltage distribution across the device, e.g. PCM of switch 1.

In a first approach units as shown in FIG. 2 can be used to design HV (high voltage)-RF-phase change switch devices devices with auxiliary driver switches.

In a second approach such units can be used for design of pure HV-RF-PCS devices without auxiliary switches with disconnected from ground heaters as well as for design of a phase change switch device with reduced number of auxiliary switches. In such approaches, a double function of phase change switches as explained above Each configuration may have special benefits. For both types of configurations, embodiments will be discussed in the following.

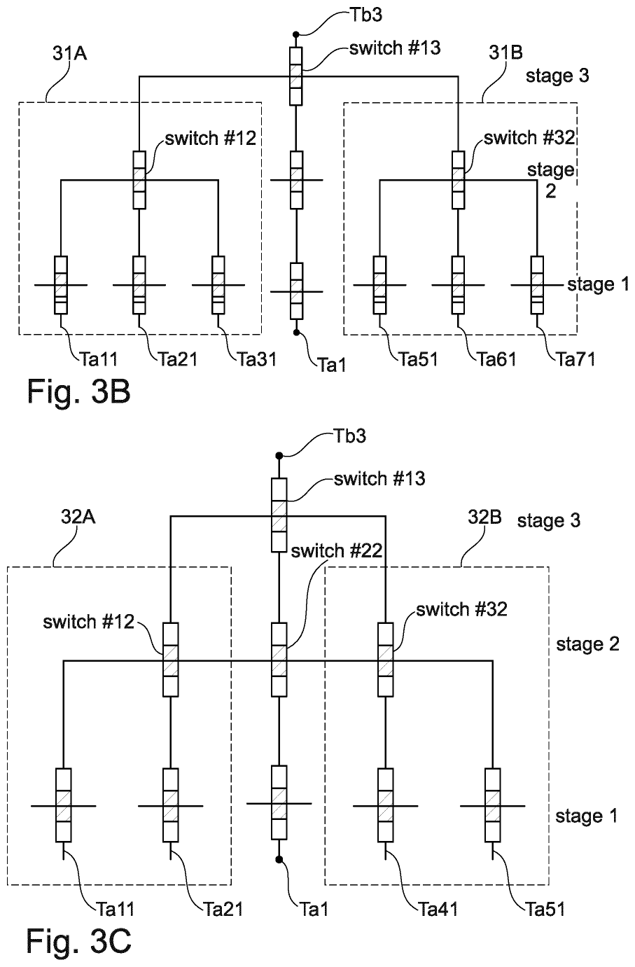

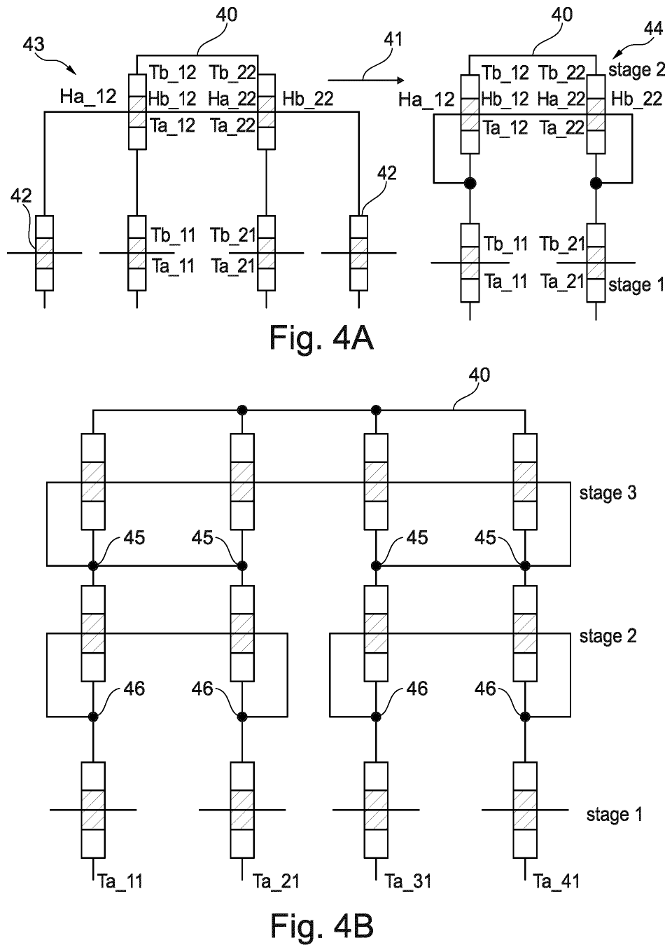

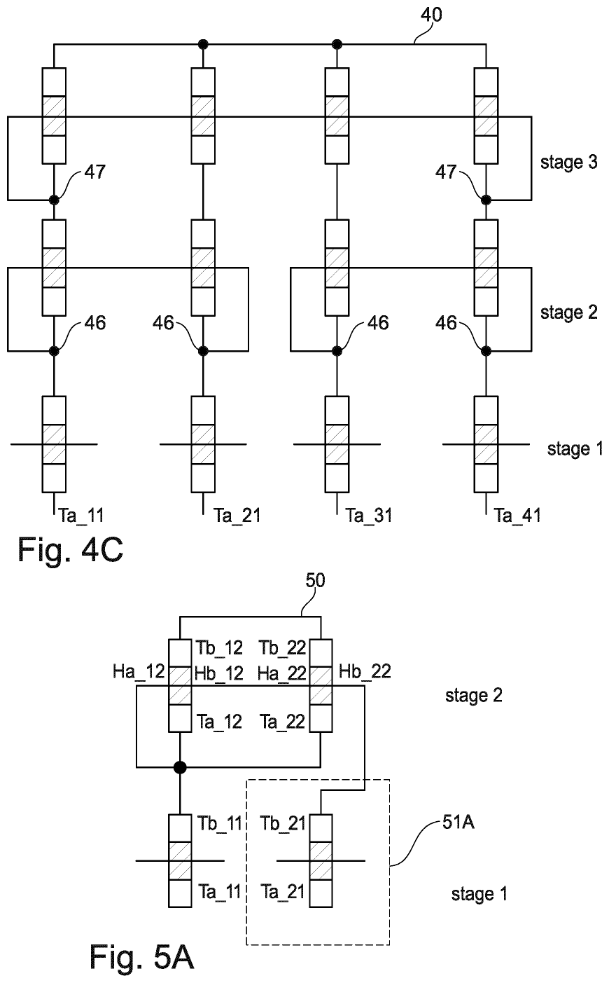

A first group of embodiments using the concept illustrated with respect to FIG. 2 according to the first approach mentioned above is to provide a phase change switch device using auxiliary PCM switch configurations for an RF PCS and is shown in FIGS. 3A to 3C. In FIGS. 3 to 5 (including respective subfigures A-E), phase change switches are arranged in stages, numbered from bottom to top in the Figures. Switch terminals and heater terminals of phase change switches in some Figures (e.g. FIG. 4A) are labeled with two numbers x and y, e.g. Ta_xy, where y gives the stage and x is a number of the PCS within the stage. Therefore, e.g. Tb_12 designates terminal Tb of switch 1 in stage 2, etc. The PCS itself, also shortly referred to as switch, is also referred to with this number, i.e. switch #xy (e. g. switch #12).

FIG. 3A shows an embodiment where a switchable RF path comprises at least one PCS, in the example shown two PCS #22 and #21 coupled in series. In operation, for example in a shunt configuration switch terminal Tb_22 may be coupled to an RF source, e.g. an antenna in an antenna tuning application, and switch terminal Ta_21 may be coupled to ground. Other applications are also possible, where PCS #22 and #21 selectively provide either a high-ohmic path (off state) or a low-ohmic path (on state) between switch terminals Tb22 and Ta21. The heater of the PCS #22 is connected to an actuation device (not shown in FIG. 3A, see actuation device 20 of FIG. 2 and the description thereof) via auxiliary PCS #11, #31 (also labeled 30A, 30B, respectively).

Heater terminals and therefore heaters of both auxiliary switches #11 and #31 as well as switch terminals Ta11, Ta31 terminals are coupled to the actuation device.

Heaters of PCS #21 can either be coupled directly to the actuation device or to additional auxiliary PCS structures (not shown), for instance the same way as it is defined for PCS #22 via switches 30A, 30B. The first case (direct coupling) may be more suitable for a shunt configuration, where e.g. switch terminal Ta_21 is coupled to ground, while the second case (coupling via additional auxiliary PCS structures) may be more suitable for a series configuration of the PCS.

FIG. 3B shows a phase change switch device having more complex PCS arrangement comprising more stacked devices, which may increase voltage handling capabilities. In this case the whole phase change switch device shown in FIG. 3A can be used as auxiliary switch arrangements 31A, 31B (i.e. each block 31A, 30B of FIG. 3B includes the phase change switch device of FIG. 3A, with terminals, and an RF path or other signal path may be between switch terminals Tb3 and Ta1. The heater of switch #13 is supplied via switch arrangements 31A, 31B via terminals Ta21, Ta61, the heater of switch #12 is supplied via terminals Tall, Ta31, and the heater of switch #32 are supplied via terminals Ta51, Ta71. The heaters of the remaining switches shown may be directly coupled to a respective actuation device. The same approach can be applied to achieve a higher degree of stacking, e.g. auxiliary switch arrangements with more stages and/or also for other PCS in the RF path.

FIG. 3C shows an embodiment where auxiliary switch arrangements 32A, 32B are merged together as shown for a shunt configuration, where in FIG. 3C the heaters of the PCS #12, #22 and #32 of stage 2 are coupled in series (including auxiliary switches and the PCS #22 in the RF path from Ta1 to Tb3). Therefore, the heaters of switches #12, #22 and #32 are supplied jointly via terminals Ta11 and Ta51, and the heater of switch #13 is supplied via terminals Ta21 and Ta41. The heaters of the remaining switches may be directly coupled to a respective actuation device.

Auxiliary switches in FIGS. 3A to 3C are used only in the actuation path for actuating one or more heaters in the signal path (e.g. RF path) and therefore they do not contribute to the reduction of ON-state resistance of the PCS structure.

Embodiments according to the second approach mentioned above are shown in FIGS. 4A to 4C. Here, some PCS have a double function as mentioned above. In some embodiments, this can be seen as merging auxiliary PCS with the main switch path(s) (e. g. RF path(s)) completely. This may be performed by shorting Ha1 and Ta1 in FIG. 2. Consequently PCS of the auxiliary switch arrangements (e.g. 30A, 30B, 31A, 31B, 32A, 32B) in FIG. 3) are merged with the PCS of the main path, e.g. PCS serve both as auxiliary switches for heater actuation and as RF switches. This is illustrated in FIG. 4A where on the left side a phase change switch device 43 which is similar to FIG. 3A, but with two parallel signal paths is shown. Switches #11 and #12 form a first signal path, and switches #21, #22 form a second signal path. Terminals Tb_12 and Tb_22 are coupled to form a single terminal 40, which can be selectively coupled to Ta_11 and/or Ta_21, e.g. a single pole (40) double throw (Ta_11, Ta_21) configuration. This is only an example configuration, and other configurations may be implemented as well.

As indicated by an arrow 41 phase change switch device 43 shown on the left side of FIG. 4A is merged to a phase change switch device 44 shown on the right side of FIG. 4A. While on the left side separate auxiliary switches 42 are provided, on the right side PCS #11 and #21 serve both as auxiliary switches and main switches. For switching the state of PCS #12, #22 power is supplied to heater terminals Ha12, Hb22 via switches #11 and #21, respectively, so in this case they have the same function as auxiliary switches 42 of phase change switch device 43 or auxiliary switches #11, #31 of FIG. 3A. Switches #11 and #21 of phase change switch device 44 are also part of the signal path from terminal 40 to terminals Ta_11, Ta_21, respectively, and therefore also serve as main switches e.g. for switching an RF signal.

FIG. 4B and FIG. 4C show higher stacked devices built with the approach of FIG. 4A. In FIG. 4B, the series connection of the heaters of stage 3 is coupled, at each end, to two respective nodes 45 between PCS of the second and third stage, whereas in FIG. 4C the coupling is only to one such node 47 for each end of the series connection. Therefore, for switching the heaters of stage 3 in FIG. 4B may be supplied in parallel via terminals Ta_11, Ta_21 at one end and Terminals Ta_31, Ta_41 at the other end, while in FIG. 4C they are only supplied via terminals Ta_11, Ta_41.

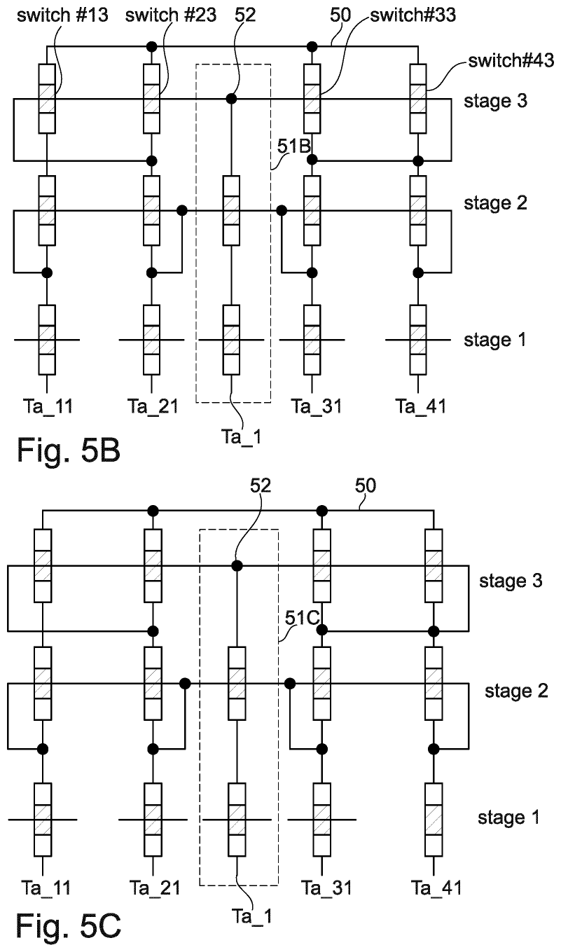

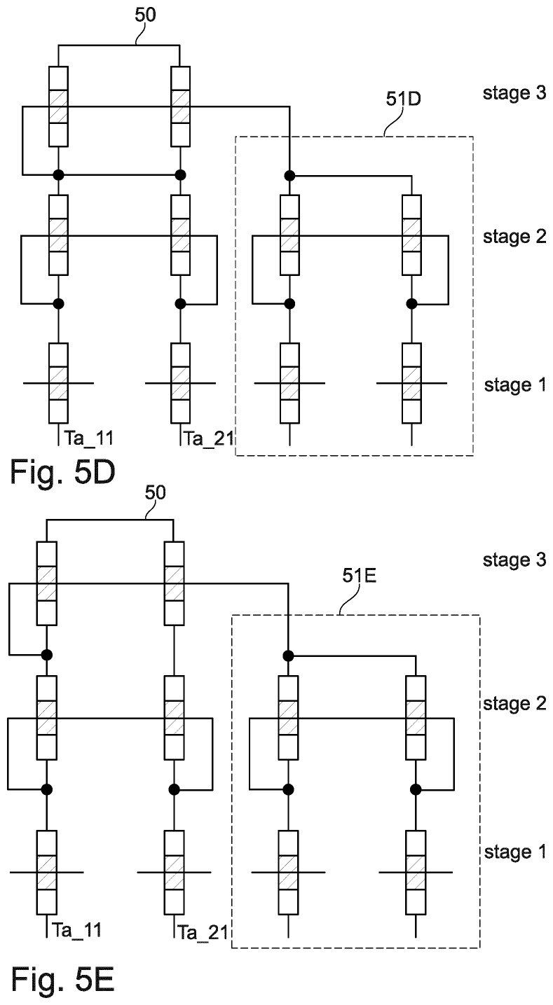

In the example of FIG. 4B and 4C, in stage 3 all four heaters are coupled in series, whereas in stage 2 two groups of two heaters are respectively coupled in series, and end terminals of the respective series connection are coupled to nodes 46 between the PCS of stage 1 and stage 2 as shown, so the heaters are supplied via the switches of stage 1. Other configurations are also possible. In FIGS. 4B and 4C, the RF path or other switchable path is between 40 and Ta_11, Ta_21,Ta_31 and Ta_41, e.g. a single pole 4 throw configuration. The number of four paths from 40 in FIGS. 4B and 4C and two paths in FIG. 4A is merely an example, and other numbers of paths may be provided. This applies also to FIGS. 3A to 3C above and FIGS. 5A to 5E described below.

Since the auxiliary circuit is always coupled to the ground (to the actuation circuit) from one side the approach of FIG. 4A-4C is applicable to the shunt configured PCS structures.

Switching of the phase change switch devices of FIGS. 4A to 4C will now be explained in more detail, with phase change switch device 44 FIG. 4A serves as an example. A similar approach may be used for the phase change switch devices of

FIG. 4B and FIG. 4C, which are essentially extensions of the concept of phase change switch device 44.

OFF→ON switching event, i.e. changing the state of the signal path from OFF to ON:

The PCS #11, #21 of stage 1 are switched ON by an actuation device directly coupled to the heaters of PCS #11, #21. . . . PCS #11, #21 in an ON state establish a DC path between the two lower terminals Ta_11 and Ta_21 and the heaters of the upper two cells (Ha_12 and Hb_22).

An actuation pulse is then applied by the actuation device between Ta_11 and Ta_21, which brings PCS #12, #22 of stage 2 into the ON state.

Therefore, the OFF-ON switching is performed from stage 1 successively to stage N for N stages.

ON→OFF switching event:

First possibility: direct conduction of current through PCM material (from Ta_11,21 to Tb_12,22), i.e. a respective actuation pulse is applied between terminals Ta11, Ta12 on the one hand and between Ta_21, Tb_22 on the other hand or only between Ta_11, Ta_21, thus flowing through all heaters of phase change switch device 44. In this case the current flowing to the PCS directly heats the phase change material for switching.

Second possibility) reversed OFF→ON sequence, i.e. the sequence explained above for the OFF→ON switching event is reversed such that first PCS #12, #22 of stage 2 are switched off, by a corresponding actuation pulse applied between Ta_11and Ta_21, and then the PCS of stage 1 are switched off by applying respective actuation pulses to their heaters directly. Maximized actuation power efficiency of the structure takes place among the benefits of the approach using switches having a double function as auxiliary switches and main switches, as less phase change material is needed and less switching is needed. As every switching of a PCS requires power, in the structures used above less power is required.

In the approach of FIGS. 4A to 4C, no pure auxiliary switches are used, which decreases the off capacitance of the switch device, which may be helpful for some applications.

In a further approach, some purely auxiliary switches are used as in FIG. 3A-3C, and others are merged as in FIGS. 4A-4C. FIGS. 5A to 5E show corresponding embodiments. Therefore, phase change switch devices of FIGS. 5A to 5E “mix” the two approaches explained above. This may facilitate the switching sequence compared to FIGS. 4A to 4C in some cases (e.g. make it more independent from a load connected to the switch device, e.g. connected to Tb_12, 22 in FIG. 5A), but may still improve e.g. the off capacitance and power efficiency.

In FIGS. 5A to 5C, an RF path is between a node 50 and terminal Ta_11 (FIG. 5A), terminals Ta_11, Ta_21, Ta_31 and Ta_41 (FIGS. 5B and 5C, i.e. a single pole 3 throw configuration) or terminals Ta_11, Ta_21 (FIG. 5E, i.e. a single pole double throw configuration). Other configurations are also possible. Auxiliary switches not provided in the signal paths (e.g. RF paths) are generally labeled with numeral 51, specifically 51A for FIG. 5A, 51B for FIG. 5B. 51C for FIG. 5C, 51D for FIG. 5D and 51E for FIG. 5E. In FIG. 5A, a PCS #11 serves both as auxiliary switch and main switch, as in the embodiments discussed with reference to FIG. 4. PCS #21 in block 51A is a pure auxiliary switch, as in the embodiments discussed with reference to FIG. 3.

Switching from OFF to ON may be performed as follows, taking FIG. 5A as an example:

First the switches of stage 1 are brought to ON state by an actuation device directly coupled to the respective heaters.

Then the PCS of stage 2 is switched on via the PCS of stage 1, by an actuation pulse applied between terminals Ta_11 and Ta_21. For this, an actuation pulse may be applied to terminal Ta_21, while Ta_11 is grounded, for example in case of a shunt configuration where Ta_11 is grounded anyway.

Switching from ON to OFF may be performed in the reverse order as the switching from OFF to ON, or by sending an actuation pulse through the switches directly, as explained above for FIG. 4A.

The same approach may be used for the embodiments of FIGS. 5B to 5E, i.e. switching from OFF to ON is performed starting in stage 1 and ending in stage N (e.g. stage 2 in case of FIG. 5A, stage 3 in case of FIGS. 5B to 5E).

The embodiments of FIGS. 5B to 5E are extensions and variations of the embodiment of FIG. 5A. FIGS. 5B and 5C show single throw 4 pole configurations similar to the phase change switch devices of FIGS. 4B and 4C, with additional auxiliary switches 51B, 51B provided as shown. The difference between FIGS. 5B and 5C is the same as explained above for FIGS. 4B and 4C, i.e. in FIG. 5B as in FIG. 4B the series connection of heaters of stage 3 is connected to two nodes in between stage 2 and stage 3 at each end (as with nodes 45 of FIG. 4B), and to one node at each end in FIG. 5C (as with nodes 47 in FIG. 5C). The additional auxiliary switches 51B, 51C are coupled to a node 52 between the heater of switch #23 and switch #33, such that an actuation pulse for switching switches #13 and #23 may be applied between terminal Ta_1 and Ta_11 (and additionally Ta_21 in FIG. 5B), and an actuation pulse for switching switches #33 and #34 may be applied between Terminal Ta_1 and terminal Ta_41 (and Ta_31 in FIG. 5B).

FIGS. 5D and 5E show single pole double throw configurations. In both FIG. 5D and 5E, heaters of stage 3 are coupled in series, and in case of FIG. 5D one end of the series connection is coupled to two nodes between stages 2 and 3, and in case of FIG. 5E to one node between stages 2 and 3, similar to the difference between FIGS. 4B and 4C or between 5B and 5C explained above. A second end of the series connection between the heaters of stage 3 is coupled to auxiliary switches 51D or 51E, respectively. The Auxiliary switches 51D, 51E by themselves are arranged and operate as in phase change switch device 44 of FIG. 4A. Stage 1 and 2 of the main path (e.g. RF path) are arranged as the left part of stages 1 and 2 of FIG. 4B or 4C.

The number of stages shown in the Figures is not to be construed as limiting, and other numbers of stages may be provided.

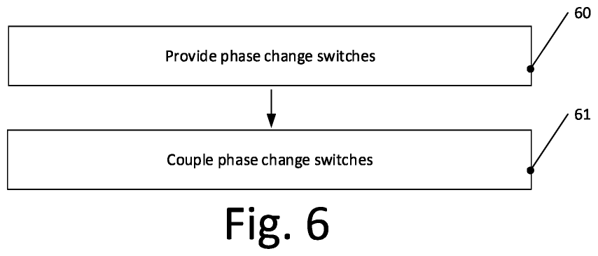

FIG. 6 illustrates a method of manufacturing a phase change switch device according to an embodiment. At 60, the method comprises providing a plurality of phase change switches. At 61, the method comprises coupling the phase changes switches to form a phase change switch device as described above referring to FIGS. 1 to 5. The providing at 60 and the coupling at 61 may be performed jointly in a manufacturing process using essentially conventional semiconductor technology, using a deposition technique for depositing the phase change material, structuring metal layers for the coupling etc.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1-16. (canceled)

17. A phase change switch device, comprising:
a first phase change switch including a phase change material, a heater device arranged to heat the phase change material, a first switch terminal electrically coupled to the phase change material, a second switch terminal electrically coupled to the phase change material, a first heater supply terminal electrically coupled to the heater device, and a second heater supply terminal electrically coupled to the heater device;
a second phase change switch including a phase change material, a heater device arranged to heat the phase change material, a first switch terminal electrically coupled to the phase change material, a second switch terminal electrically coupled to the phase change material, a first heater supply terminal electrically coupled to the heater device, and a second heater supply terminal electrically coupled to the heater device,
wherein the first switch terminal of the second phase change switch is electrically coupled to the first heater supply terminal of the first phase change switch.

18. The phase change switch device of claim 17, wherein the first switch terminal of the second phase change switch is electrically coupled to the second switch terminal of the first phase change switch.

19. The phase change switch device of claim 17, further comprising an actuation device configured:
for switching the first phase change switch and the second phase change switch between an on state and an off state, to supply power to the first heater terminal of the first phase change switch via the first switch terminal of the second phase change switch, the phase change material of the second phase change switch and the second switch terminal of the second phase change switch while the second phase change switch is switched on.

20. A phase change switch device, comprising:
N stages, wherein N>=2, each stage comprising one or more phase change switches, each phase change switch including a phase change material, a heater device arranged to heat the phase change material, a first switch terminal electrically coupled to the phase change material, a second switch terminal electrically coupled to the phase change material, a first heater supply terminal electrically coupled to the heater device, and a second heater supply terminal electrically coupled to the heater device,
wherein for each phase change switch of at least one stage i, i=N . . . 2, each of the first and second heater terminals is coupled either to a first or second heater terminal of another phase change switch of stage i or to a first switch terminal of a phase change switch of stage i−1.

21. The phase change switch device of claim 20, wherein the second switch terminal of at least one phase change switch of stage i, i=N . . . 2, is coupled to a first switch terminal of a phase change switch of stage i−1.

22. The phase change switch device of claim 21, wherein the second switch terminal of each phase change switch of stage i, i=N . . . 2, is coupled to a first switch terminal of a phase change switch of stage i−1.

23. The phase change switch device of claim 20, wherein for each stage i, i=N−1 . . . 1, the number of phase change switches is equal to or greater than a number of phase change switches in stage i+1.

24. The phase change switch device of claim 23, wherein for at least one stage i, i=N−. . . 1, the number of phase change switches is equal to a number of phase change switches in stage i+1.

25. The phase change switch device of claim 24, wherein for each stage i, i=N−1 . . . 1, the number of phase change switches is equal to a number of phase change switches in stage i+1.

26. The phase change switch device of claim 20, further comprising an actuation device configured to switch the phase changes switches between an on state and an off state.

27. The phase change switch device of claim 26, wherein in an off state of the phase change switch device, the heater device of each phase change switch of stage i, i=N . . . 2, is decoupled from the actuation device.

28. The phase change switch device of claim 26, wherein in an off state of the phase change switch device, the heater device of each phase change switch of stage i, i=N . . . 2, is decoupled from ground by at least one phase change switch of stage i−1.

29. The phase change switch device of claim 26, wherein in an off state of the phase change switch device, the heater device of each phase change switch of stage i, i=N . . . 2, is decoupled from a reference potential by at least one phase change switch of stage i−1.

30. The phase change switch device of claim 26, wherein for switching a state of the phase change switch device from off to on, the actuation device is configured to change states of phase change switches starting in stage 1 and ending in stage N.

31. The phase change switch device of claim 20, wherein in at least one stage i, i=N−1 . . . 2, the phase change switches are grouped into M groups, M>=1, each including K phase change switches, K>=1, wherein for each group:
for a phase change switch j=1, the first heater terminal is electrically coupled to the first switch terminal of a phase change switch of stage i−1;
for K>1 and for each phase change switch j, j=1. . . . K−1, the second heater terminal is electrically coupled to the first heater terminal of phase change switch j+1; and
for phase change switch j=K, the second heater terminal is coupled to the first switch terminal (Ta) of another phase change switch of stage i−1.

32. The phase change switch device of claim 20, wherein in at least one stage i, i=N−1 . . . 2, the first heater terminal of at least one phase change switch of stage i is coupled to a first switch terminal of a phase change switch of stage i−1, the second heater terminal of at least one another phase change switch of stage i is coupled to a first switch terminal of a phase change switch of stage i−1, and first and second heater terminals of all phase change switches of stage i that are not coupled to a first switch terminal of a phase change switch of stage i−1 are coupled with another first or second heater terminal of a phase change switch of stage i.

33. A phase change switch device, comprising:
N stages, wherein N>=2,
wherein a first phase change switch of stage i, i=N . . . 2, comprises a phase change material, a heater device arranged to heat the phase change material, a first switch terminal electrically coupled to the phase change material, a second switch terminal electrically coupled to the phase change material, a first heater supply terminal electrically coupled to the heater device, and a second heater supply terminal electrically coupled to the heater device,
wherein a phase change switch of stage i−1 comprises a phase change material, a heater device arranged to heat the phase change material, a first switch terminal electrically coupled to the phase change material, a second switch terminal electrically coupled to the phase change material, a first heater supply terminal electrically coupled to the heater device, and a second heater supply terminal electrically coupled to the heater device,
wherein for at least one stage i, i=N . . . 2, the first switch terminal of the second phase change switch is electrically coupled to the first heater supply terminal of the first phase change switch.
